(19) United States
(12) Patent Application Publication
(10) Pub. No.: US 2022/0139843 A1
(43) Pub. Date: May 5, 2022

(54) RESILIENT ELECTRICAL CONNECTORS FOR ELECTROMAGNETIC INTERFERENCE SHIELDING STRUCTURES IN INTEGRATED CIRCUIT ASSEMBLIES

(71) Applicant: INTEL CORPORATION, Santa Clara, CA (US)

(72) Inventors: Jun LU, Shanghai (CN); Wei LIAO, Shanghai (CN); Chen ZHANG, Shanghai (CN); Guangying ZHANG, Shanghai (CN); Liguang DU, Shanghai (CN); Chuansheng LIU, Shanghai (CN); Michael LEDDIGE, Hillsboro, OR (US); Weimin SHI, Beaverton, OR (US); Eduardo MICHEL, Jalisco (MX); Guillermo RENTERIA ZAMUDIO, Phoenix, AZ (US)

(73) Assignee: INTEL CORPORATION, Santa Clara, CA (US)

(21) Appl. No.: 17/428,565

(22) PCT Filed: Apr. 10, 2019
(86) PCT No.: PCT/CN2019/081994

§ 371 Date: Aug. 4, 2021

(51) Int. Cl. H01L 23/552; H01L 23/00

(52) U.S. Cl. CPC H01L 23/552; H01L 2924/3025; H01L 24/72

(57) ABSTRACT

An integrated circuit assembly may be formed having at least one integrated circuit device electrically attached to an electronic substrate. The integrated circuit assembly may further include at least one electromagnetic interference structure attached to the electronic substrate adjacent to the at least one integrated circuit device. The at least one electromagnetic interference structure may be electrically attached to the electronic substrate with at least one resilient connector extending therebetween. In one embodiment, the at least one electromagnetic interference structure may be grounded to the electronic substrate.

### TECHNICAL FIELD

Embodiments of the present description generally relate to electromagnetic interference shielding for integrated circuit assemblies, and, more specifically, to electrically connecting an electromagnetic interference shielding structure to a ground connection in an electronic substrate in an integrated circuit assembly with a resilient electrical connector.

### BACKGROUND

The integrated circuit industry is continually striving to produce ever faster, smaller, and thinner integrated circuit packages for use in various electronic products, including, but not limited to, computer server products and portable products, such as portable computers, electronic tablets, cellular phones, digital cameras, and the like.

As integrated circuit products and packages become smaller, the integrated circuit devices device within are positioned closer to one another. The closeness of the integrated circuit devices can give rise to problems with electromagnetic interference. Electromagnetic interference occurs when electromagnetic fields are generated by the integrated circuit devices, which may interfere with operation of other integrated circuits within the products or packages. One approach to reduce such electromagnetic field interference is through the use of a Faraday or electromagnetic interference (“EMI”) structures, such as cages, frames, or shields, which are a highly electrically conductive structures that are grounded and enclose or surround a portion of selected integrated circuit devices within a product or package. Such EMI structures not only contain electromagnetic fields generated by the integrated circuit device(s) that it encloses or surrounds, but also prevents external or ambient electromagnetic fields, such as radio frequency energy, from affecting the functionality of the enclosed integrated circuit device(s), as will be understood to those skilled in the art.

The integrated circuit device(s) that are enclosed or surrounded by the EMI structure are generally attached to an electronic substrate in a “flip chip” configuration, wherein the integrated circuit device(s) are assembled on a first surface of the electronic substrate using interconnects, such as solder bumps or balls. The EMI structure may also be attached to the first surface for the electronic substrate, wherein the EMI structure is electrically connected to the ground line/plane within the electronic structure. This electrical connection between the EMI structure and the electronic substrate is general a rigid connection between the material of the EMI structure (e.g. metal) and the material of the ground line/plane (e.g. metal). This rigid connection may induce stresses in the electronic substrate, particular during thermal cycling the operation of the integrated circuit package, which may lead to the failure of the interconnects between the integrated circuit device(s) and the electronic substrate.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly having an electromagnetic interference structure electrically attached to an electronic substrate with a resilient connector, according to one embodiment of the present description.

FIG. 2 is a top plan view along view A-A of FIG. 1 illustrating the integrated circuit assembly having a heat dissipation device in thermal contact with an integrated circuit device, according to an embodiment of the present description.

FIG. 3 is an oblique plan view of a resilient connector within a recess of an electromagnetic interference structure, according to one embodiment of the present description.

FIG. 4 is a side cross-sectional view of an integrated circuit assembly having a U-shaped resilient connector prior to attachment to the electronic substrate, according to an embodiment of the present description.

FIG. 5 is a side cross-sectional view of an integrated circuit assembly of FIG. 4 after attachment to the electronic substrate, according to one embodiment of the present description.

FIG. 6 is a side cross-sectional view of an integrated circuit assembly having a metal filled polymer resilient connector prior to attachment to the electronic substrate, according to an embodiment of the present description.

FIG. 7 is a side cross-sectional view of an integrated circuit assembly of FIG. 6 after attachment to the electronic substrate, according to one embodiment of the present description.

FIG. 8 is a side cross-sectional view of an integrated circuit assembly having a coiled spring resilient connector prior to attachment to the electronic substrate, according to an embodiment of the present description.

FIG. 9 is a side cross-sectional view of an integrated circuit assembly of FIG. 8 after attachment to the electronic substrate, according to one embodiment of the present description.

FIG. 10 is a side cross-sectional view of the integrated circuit assembly of FIG. 1 further including a backing plate, according to one embodiment of the present description.

FIG. 11 is a flow chart of a process of fabricating an integrated circuit assembly, according to an embodiment of the present description.

FIG. 12 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include an integrated circuit assembly having at least one integrated circuit device electrically attached to an electronic substrate. The integrated circuit assembly may further include at least one electromagnetic interference structure attached to the electronic substrate adjacent to the at least one integrated circuit device. The at least one electromagnetic interference structure may be electrically attached to the electronic substrate with at least one resilient connector extending therebetween. In one embodiment, the at least one electromagnetic interference structure may be grounded to the electronic substrate.

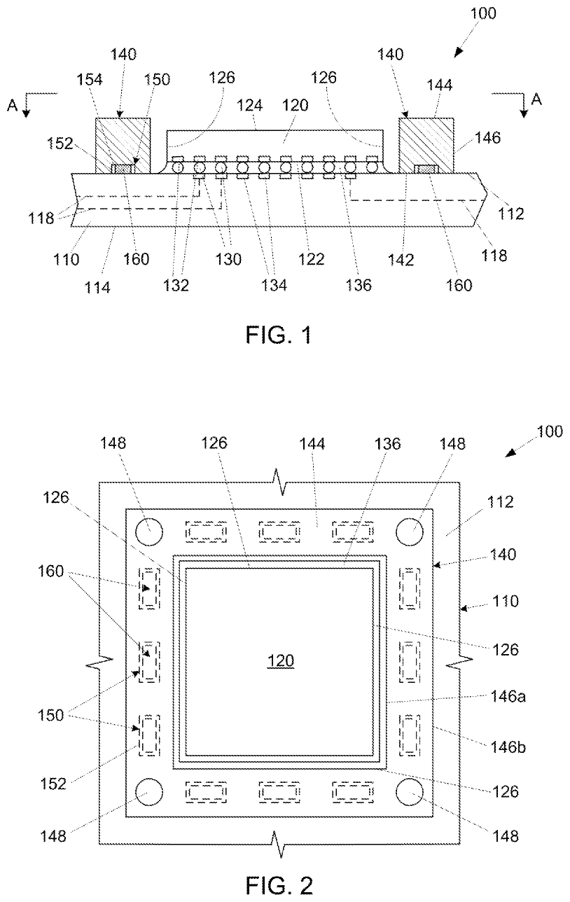

As shown in FIG. 1, an integrated circuit assembly 100, such as an integrated circuit package, may be formed by first providing or forming an electronic substrate 110, such as an interposer, a printed circuit board, a motherboard, or the like. At least one integrated circuit device 120 may be attached to a first surface 112 of the electronic substrate 110 with a plurality of interconnects 130. The plurality of interconnects 130 may extend between bond pads 132 formed in or on a first surface 122 (also known as the “active surface”) of the integrated circuit device 120, and substantially mirror-image bond pads 134 formed in or on the first surface 112 of the electronic substrate 110. The at least one integrated circuit device 120 may further include a second surface 124 (also known as the “back surface”) opposing the first surface 122 and at least one side 126 extending between the first surface 122 and the second surface 124 of the at least one integrated circuit device 120. The least one integrated circuit device 120 may be any appropriate device, including, but not limited to, a microprocessor, a multichip package, a chipset, a graphics device, a wireless device, a memory device, an application specific integrated circuit device, combinations thereof, stacks thereof, or the like. The interconnects 130 may be any appropriate electrically conductive material or structure, including but not limited to, solder balls, metal bumps or pillars, metal filled epoxies, or a combination thereof. In one embodiment, the interconnects 130 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment, the interconnects 130 may be copper bumps or pillars. In a further embodiment, the interconnects 130 may be metal bumps or pillars coated with a solder material.

An underfill material 136, such as an epoxy material, may be disposed between the first surface 122 of the integrated circuit device 120 and the first surface 112 of the electronic substrate 110, and surrounding the plurality of interconnects 130. As will be understood to those skilled in the art, the underfill material 136 may be dispensed between the first surface 122 of the integrated circuit device 120 and the first surface 112 of the electronic substrate 110 as a viscous liquid and then hardened with a curing process. The underfill material 136 may also be a molded underfill material. The underfill material 136 may provide structural integrity and may prevent contamination, as will be understood to those skilled in the art.

As further shown in FIG. 1, the electronic substrate 110 may provide electrical communication through conductive routes 118 (illustrated as dashed lines) between the integrated circuit device 120 and external components (not shown). These conduction routes 118 may be referred to herein as “metallization”. As will be understood to those skilled in the art, the bond pads 132 of the integrated circuit device 120 may be in electrical communication with integrated circuitry (not shown) within the integrated circuit device 120.

The electronic substrate 110 may comprise a plurality of dielectric material layers (not shown in FIG. 1), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, as well as laminates or multiple layers thereof, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. The conductive routes 118 may be a combination of conductive traces (not shown) and conductive vias (not shown) that extend through the plurality of dielectric material layers (not shown). These conductive traces and conductive vias, and processes of forming the same, are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood by those skilled in the art, the electronic substrate 110 may be a cored substrate or a coreless substrate.

As shown in FIG. 1, the integrated circuit assembly 100 may include at least one electromagnetic interference structure 140 attached to the electronic substrate 110 adjacent to the at least one integrated circuit device 120. The electromagnetic interference structure 140 may include a first surface 142 adjacent to the electronic substrate 110, an opposing second surface 144, and at least one sidewall 146 extending between the first surface 142 and the second surface 144. As further shown in FIG. 1, the electromagnetic interference structure 140 may include a recess 150 extending into the electromagnetic interference structure 140 from the first surface 142 thereof. In one embodiment of the present description, the recess 150 may comprise at least one wall 152 extending from the first surface 142 of the electromagnetic interference structure 140 to a bottom surface 154 of the recess 150.

As further shown in FIG. 1, a resilient connector 160 may extend from the bottom surface 154 of the recess 150 to the electronic substrate 110, wherein the resilient connector 160 make electrical contact between the electromagnetic interference structure 140 and the electronic substrate 110, as will be discussed. The term “resilient” with regard to the resilient connector 160 of the present description is defined to be a material or structure which is capable of compressing under a bias or pressure and return to substantially its original shape when the bias or pressure is removed. The resilient connector 160 may be comprised of any appropriate electrically conductive material, including, but not limited to metals (such as copper, aluminum, silver, nickel, gold, alloys thereof, and the like), conductive polymer (such as metal filled epoxies), and the like.

As shown in FIG. 2, the electromagnetic interference structure 140 may be a frame-like structure defined by an inner sidewall 146a surrounding the integrated circuit device 120 and an outer sidewall 146b surrounding the inner sidewall 146a. The electromagnetic interference structure 140 may be secured to the electronic substrate 110 with at least one securing mechanisms 148, such as bolts, screws, and the like. As shown in dashed lines, recesses 150 and their respective resilient connectors 160 may be distributed around the electromagnetic interference structure 140.

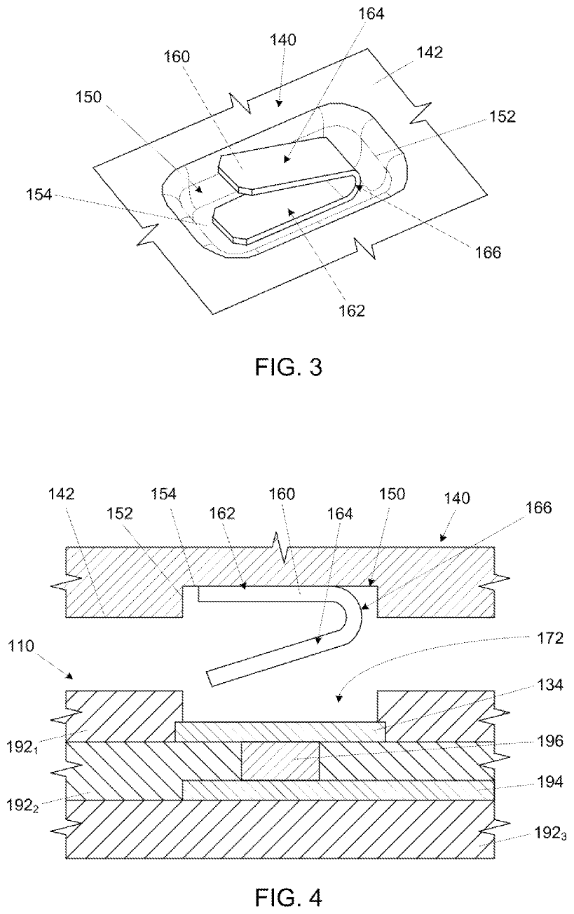

The resilient connector 160 may have any appropriate configuration. In one embodiment of the present description, as shown in FIGS. 3-5, the resilient connector 160 may be a U-shaped biasing mechanism or spring. The resilient connector 160 may comprise a first contact structure 162, a second contact structure 164, and arcuate or C-shape spring portion 166 connecting the first contact structure 162 to the second contact structure 164. In one embodiment, the first contact structure 162 may be attached to the bottom surface 154 of the recess 150.

As shown in FIG. 4 and as previously discussed, the electronic substrate 110 may be formed with a plurality of dielectric material layers 192₁-192₃, a plurality of conductive routes 118 (see FIG. 1) formed from at least one conductive trace 194 formed in or on the dielectric material layers 192₁-192₃, respectively, which are connected with at least one conductive via 196, and at least one bond pad 134. The uppermost dielectric layer 192₁ may include an opening 172 extending therethrough to expose at least a portion of the at least one bond pad 134. In one embodiment, the uppermost dielectric layer 192₁ may be a solder resist material, as known in the art.

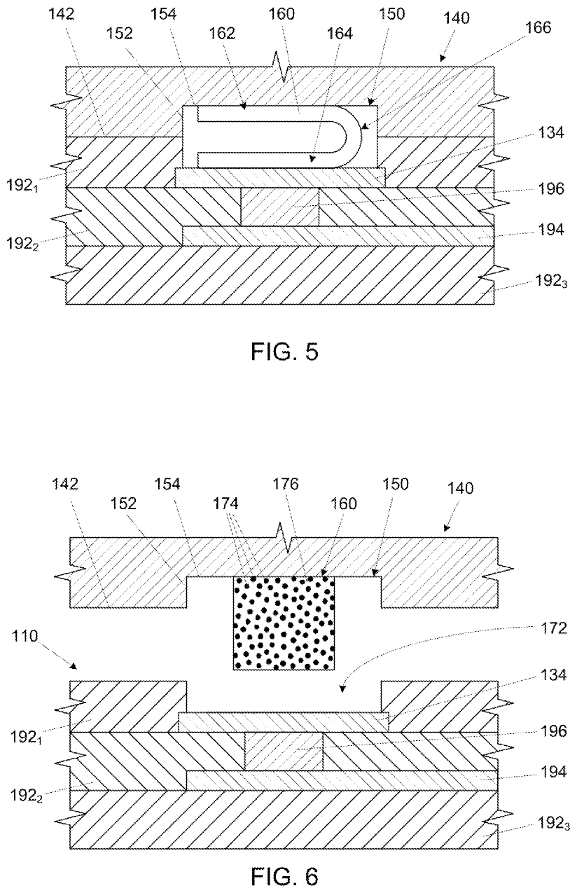

As shown in FIG. 4, the resilient connector 160 may be aligned over the opening 172. The electromagnetic interference structure 140 may be brought into contact with the electronic substrate 110, as shown in FIG. 5, such that the resilient connector 160 is biased and compressed against the bond pad 134 of the electronic substrate 110. In one embodiment, the illustrated bond pad 134 is electrically couple to electrical ground within the electronic substrate 110.

As will be understood, the dielectric materials layers 192₁-192₃ used to form the electronic substrate 110 are generally more flexible than the materials used to form the conductive routes 118 and bond pads 134, such as metal materials, and the embodiments of the present description result in flexible electrical contact between the electromagnetic interference structure 140 and the electronic substrate 110. Thus, less stress may be induced in the electronic substrate 110 during thermal cycling in the operation of the integrated circuit assembly 100, which may prevent the failure of the interconnects 130 between the integrated circuit device 120 and the electronic substrate 110, as previously discussed.

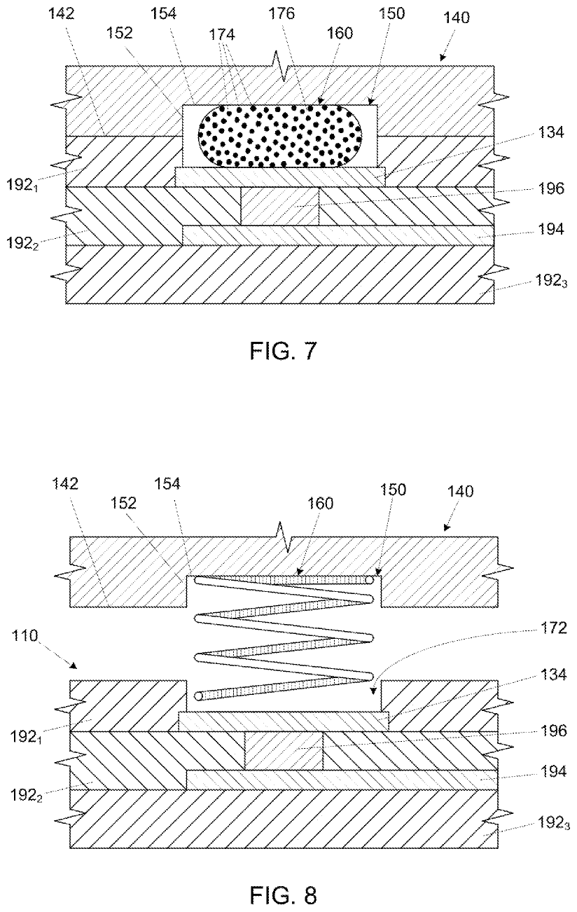

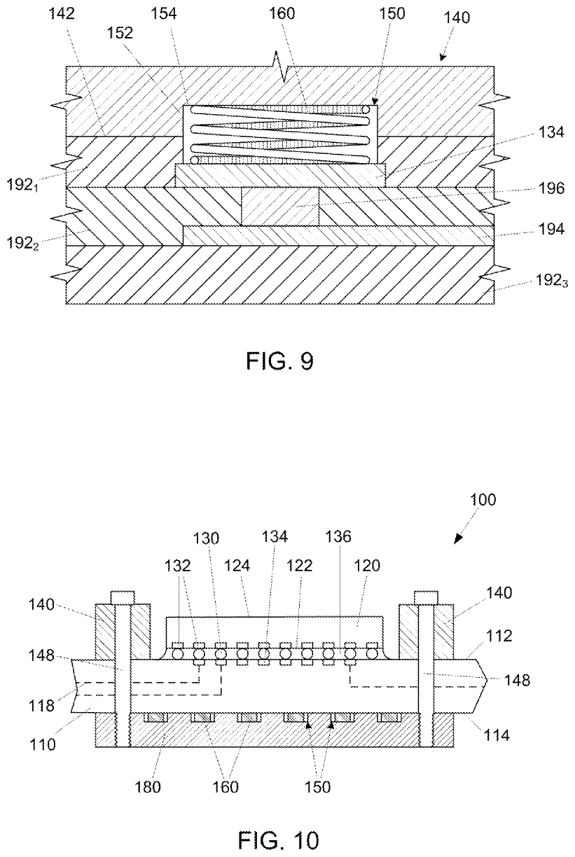

Although FIGS. 3-5 illustrate a specific U-shaped resilient connector 160, the embodiments of the present description are not so limited. In one embodiment, the resilient connector 160 may be a flexible, metal filled polymer (such as metal particles 174 dispersed in a polymer carrier 176), shown in an unattached, uncompressed state in FIG. 6 and in an attached, compressed state in FIG. 7. In a further embodiment, the resilient connector 160 may be a coiled spring, shown in an unattached, uncompressed state in FIG. 8 and in an attached, compressed state in FIG. 9.

In a further embodiment of the present description, as illustrated in FIG. 10, the integrated circuit assembly 100 may further include a backing plate 180, as known in the art, on a second surface 114 of the electronic substrate 110. The electromagnetic interference structure 140 and the backing plate 180 may be secured to the electronic substrate 110 with the at least one securing mechanisms 148, such as bolts, screws, and the like. The backing plate 180 may be electrically conductive, such that it assists with electromagnetic interference protection. The backing plate 180 may include at least one recess 150, such as that shown with regard to the electromagnetic interference structure 140 (see FIG. 1) and at least one resilient connector 160 may extend from the recess 150 to the electronic substrate 110, wherein the resilient connector 160 make electrical contact between the backing plate 180 and the electronic substrate 110 in the same manner and structures as previously described with regard to electromagnetic interference structure 140 and the electronic substrate 110, hereby incorporated herein by reference.

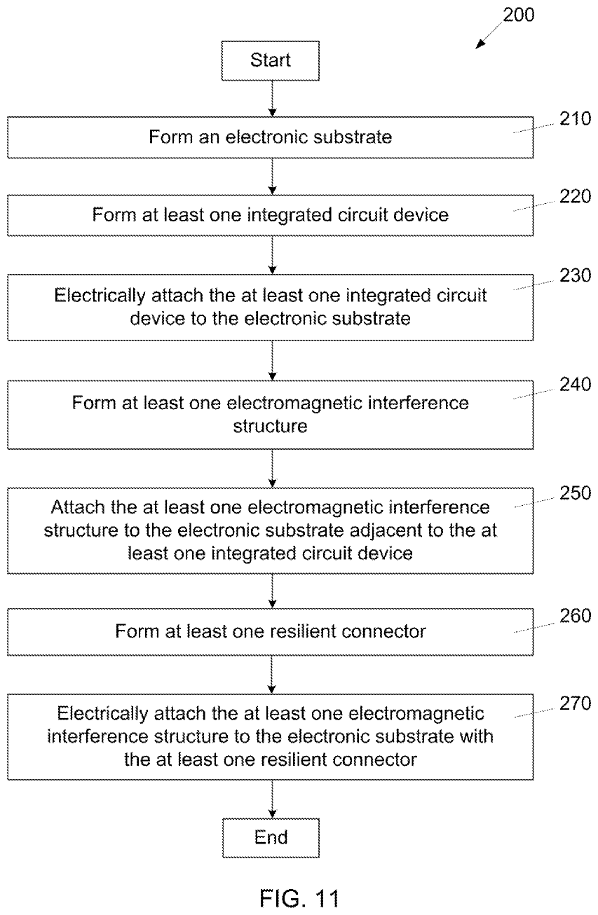

FIG. 11 is a flow chart of a process 200 of fabricating an integrated circuit assembly according to an embodiment of the present description. As set forth in block 210, an electronic substrate may be formed. At least one integrated circuit device may be formed, as set forth in block 220. As set forth in block 230, the at least one integrated circuit device may be electrically attached to the electronic substrate. At least one electromagnetic interference structure may be formed, as set forth in block 240. As set forth in block 250, the at least one electromagnetic interference structure may be attached to the electronic substrate adjacent to the at least one integrated circuit device. At least one resilient connector may be formed, as set forth in block 260. As set forth in block 270, the at least one electromagnetic interference structure may be electrically attached to the at least one integrated circuit device with the at least one resilient connector.

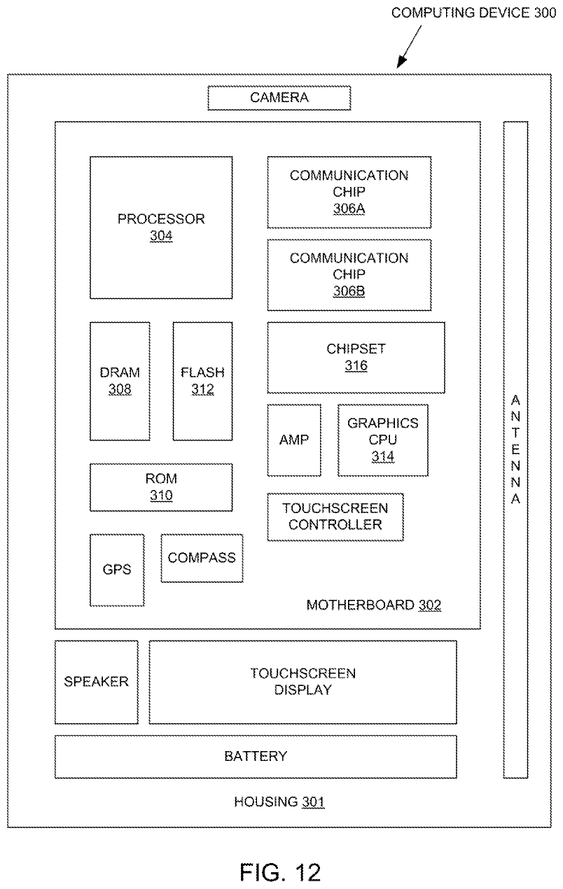

FIG. 12 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an electronic substrate, at least one integrated circuit device electrically attached to the electronic substrate, at least one electromagnetic interference structure attached to the electronic substrate adjacent the at least integrated circuit device, and at least one resilient connector extending between and electrically attaching the at least one electromagnetic interference structure and the at least one integrated circuit device.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-12. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an integrated circuit assembly, comprising an electronic substrate, at least one integrated circuit device electrically attached to the electronic substrate, at least one integrated circuit device attached to the electronic substrate adjacent to the at least one integrated circuit device, and at least one resilient connector extending between and electrically attaching the at least one electromagnetic interference structure and the at least one integrated circuit device.

In Example 2, the subject matter of Example 1 can optionally include a recess in the at least one electromagnetic interference structure and wherein the at least one resilient connector resides at least partially within the recess.

In Example 3, the subject matter of Example 2 can optionally include the recess comprising at least one wall extending from a first surface of the electromagnetic interference structure to a bottom surface of the recess.

In Example 4, the subject matter of Example 3 can optionally include the resilient connector being attached to the bottom surface of the recess.

In Example 5, the subject matter of any of Examples 1 to 4 can optionally include the electronic substrate comprising at least one dielectric layer, at least one bond pad, and at least one opening extending through the at least one dielectric layer, wherein the at least one resilient connector extends through the opening to contact the at least one bond pad.

In Example 6, the subject matter of any of Examples 1 to 5 can optionally include the at least one resilient connector comprising a first contact structure, a second contact structure, and an arcuate spring portion extending between the first contact structure and the second contact structure.

In Example 7, the subject matter of any of Examples 1 to 5 can optionally include the at least one resilient connector comprising a coiled spring.

In Example 8, the subject matter of any of Examples 1 to 5 can optionally include the at least one resilient connector comprising a metal filled polymer.

In Example 9, the subject matter of any of Examples 1 to 8 can optionally include the electromagnetic interference structure substantially surrounding the at least one integrated circuit device.

In Example 10, the subject matter of any of Examples 1 to 9 can optionally include a backing plate on a side of the electronic substrate opposite the electromagnetic interference structure.

In Example 11, the subject matter of Example 10 can optionally include at least one resilient connector extending between and electrically attaching the backing plate and the at least one integrated circuit device.

Example 12 is an electronic system comprising a board; and an integrated circuit package electrically attached to the board, wherein the integrated circuit assembly comprises an integrated circuit assembly, comprising an electronic substrate, at least one integrated circuit device electrically attached to the electronic substrate, at least one integrated circuit device attached to the electronic substrate adjacent to the at least one integrated circuit device, and at least one resilient connector extending between and electrically attaching the at least one electromagnetic interference structure and the at least one integrated circuit device.

In Example 13, the subject matter of Example 12 can optionally include a recess in the at least one electromagnetic interference structure and wherein the at least one resilient connector resides at least partially within the recess.

In Example 14, the subject matter of Example 13 can optionally include the recess comprising at least one wall extending from a first surface of the electromagnetic interference structure to a bottom surface of the recess.

In Example 15, the subject matter of Example 14 can optionally include the resilient connector being attached to the bottom surface of the recess.

In Example 16, the subject matter of any of Examples 12 to 15 can optionally include the electronic substrate comprising at least one dielectric layer, at least one bond pad, and at least one opening extending through the at least one dielectric layer, wherein the at least one resilient connector extends through the opening to contact the at least one bond pad.

In Example 17, the subject matter of any of Examples 12 to 16 can optionally include the at least one resilient connector comprising a first contact structure, a second contact structure, and an arcuate spring portion extending between the first contact structure and the second contact structure.

In Example 18, the subject matter of any of Examples 12 to 16 can optionally include the at least one resilient connector comprising a coiled spring.

In Example 19, the subject matter of any of Examples 12 to 16 can optionally include the at least one resilient connector comprising a metal filled polymer.

In Example 20, the subject matter of any of Examples 12 to 19 can optionally include the electromagnetic interference structure substantially surrounding the at least one integrated circuit device.

In Example 21, the subject matter of any of Examples 12 to 20 can optionally include a backing plate on a side of the electronic substrate opposite the electromagnetic interference structure.

In Example 22, the subject matter of Example 21 can optionally include at least one resilient connector extending between and electrically attaching the backing plate and the at least one integrated circuit device.

Example 23 is a method of fabrication an integrated circuit assembly may comprise forming an electronic substrate, forming at least one integrated circuit device, electrically attaching the at least one integrated circuit device to the electronic substrate, electrically attaching the at least one integrated circuit device to the electronic substrate, forming at least one electromagnetic interference structure, attaching the at least one electromagnetic interference structure to the electronic substrate adjacent the at least one integrated circuit device, forming at least one resilient connector, and electrically attaching the at least one electromagnetic interference structure and the at least one integrated circuit device with the at least one resilient connector.

In Example 24, the subject matter of Example 23 can optionally include forming a recess in the at least one electromagnetic interference structure and wherein the at least one resilient connector resides at least partially within the recess.

In Example 25, the subject matter of Example 24 can optionally include forming the recess comprising forming at least one wall extending from a first surface of the electromagnetic interference structure to a bottom surface of the recess.

In Example 26, the subject matter of Example 25 can optionally include attaching the resilient connector to the bottom surface of the recess.

In Example 27, the subject matter of any of Examples 23 to 26 can optionally include the electronic substrate comprising forming at least one dielectric layer, forming at least one bond pad, and forming at least one opening extending through the at least one dielectric layer, wherein the at least one resilient connector extends through the opening to contact the at least one bond pad.

In Example 28, the subject matter of any of Examples 23 to 27 can optionally include forming the at least one resilient connector comprising a first contact structure, a second contact structure, and an arcuate spring portion extending between the first contact structure and the second contact structure.

In Example 29, the subject matter of any of Examples 23 to 27 can optionally include forming the at least one resilient connector comprising forming a coiled spring.

In Example 30, the subject matter of any of Examples 23 to 27 can optionally include forming the at least one resilient connector comprising forming a metal filled polymer.

In Example 31, the subject matter of any of Examples 23 to 30 can optionally include the electromagnetic interference structure substantially surrounding the at least one integrated circuit device.

In Example 32, the subject matter of any of Examples 23 to 31 can optionally include attaching a backing plate on a side of the electronic substrate opposite the electromagnetic interference structure.

In Example 33, the subject matter of Example 32 can optionally include forming at least one resilient connector extending between and electrically attaching the backing plate and the at least one integrated circuit device.

Having thus described in detail embodiments of the present invention, it is understood that the invention defined by the appended claims is not to be limited by particular details set forth in the above description, as many apparent variations thereof are possible without departing from the spirit or scope thereof.

1-33. (canceled)

34. An integrated circuit assembly, comprising:
an electronic substrate;
at least one integrated circuit device electrically attached to the electronic substrate;
at least one electromagnetic interference structure attached to the electronic substrate adjacent to the at least one integrated circuit device; and
at least one resilient connector extending between and electrically attaching the at least one electromagnetic interference structure and the at least one integrated circuit device.

35. The integrated circuit assembly of claim 34, further comprising a recess in the at least one electromagnetic interference structure and wherein the at least one resilient connector resides at least partially within the recess.

36. The integrated circuit assembly of claim 35, wherein the recess comprises at least one wall extending from a first surface of the electromagnetic interference structure to a bottom surface of the recess.

37. The integrated circuit assembly of claim 36, wherein the resilient connector is attached to the bottom surface of the recess.

38. The integrated circuit assembly of claim 34, wherein the electronic substrate comprises at least one dielectric layer, at least one bond pad, and at least one opening extending through the at least one dielectric layer, wherein the at least one resilient connector extends through the opening to contact the at least one bond pad.

39. The integrated circuit assembly of claim 34, wherein the at least one resilient connector comprises a first contact structure, a second contact structure, and an arcuate spring portion extending between the first contact structure and the second contact structure.

40. The integrated circuit assembly of claim 34, wherein the at least one resilient connector comprises a coil spring.

41. The integrated circuit assembly of claim 34, wherein the at least one resilient connector comprises a metal filled polymer.

42. The integrated circuit assembly of claim 34, wherein the electromagnetic interference structure substantially surrounding the at least one integrated circuit device.

43. The integrated circuit assembly of claim 34, further comprising a backing plate on a side of the electronic substrate opposite the electromagnetic interference structure.

44. The integrated circuit assembly of claim 43, further comprising at least one resilient connector extending between and electrically attaching the backing plate and the at least one integrated circuit device.

45. An electronic system, comprising:
a board; and
an integrated circuit package electrically attached to the board, wherein the integrated circuit package comprises:
an electronic substrate;
at least one integrated circuit device electrically attached to the electronic substrate;
at least one electromagnetic interference structure attached to the electronic substrate adjacent the at least one integrated circuit device; and
at least one resilient connector extending between and electrically attaching the at least one electromagnetic interference structure and the at least one integrated circuit device.

46. The electronic system of claim 45, further comprising a recess in the at least one electromagnetic interference structure and wherein the at least one resilient connector resides at least partially within the recess.

47. The electronic system of claim 46, wherein the recess comprises at least one wall extending from a first surface of the electromagnetic interference structure to a bottom surface of the recess.

48. The electronic system of claim 47, wherein the resilient connector is attached to the bottom surface of the recess.

49. The electronic system of claim 45, wherein the electronic substrate comprises at least one dielectric layer, at least one bond pad, and at least one opening extending through the at least one dielectric layer, wherein the at least one resilient connector extends through the opening to contact the at least one bond pad.

50. The electronic system of claim 45, wherein the electromagnetic interference structure substantially surrounding the at least one integrated circuit device.

51. The electronic system of claim 45, further comprising a backing plate on a side of the electronic substrate opposite the electromagnetic interference structure.

52. The electronic system of claim 51, further comprising at least one resilient connector extending between and electrically attaching the backing plate and the at least one integrated circuit device.

53. A method of fabricating an integrated circuit assembly, comprising:
forming an electronic substrate;
forming at least one integrated circuit device;
electrically attaching the at least one integrated circuit device to the electronic substrate;
forming at least one electromagnetic interference structure;
attaching the at least one electromagnetic interference structure to the electronic substrate adjacent the at least one integrated circuit device;
forming at least one resilient connector; and
electrically attaching the at least one electromagnetic interference structure and the at least one integrated circuit device with the at least one resilient connector.

54. The method of claim 53, further comprising forming a recess in the at least one electromagnetic interference structure and wherein the at least one resilient connector resides at least partially within the recess.

55. The method of claim 54, wherein forming the recess comprises forming at least one wall extending from a first surface of the electromagnetic interference structure to a bottom surface of the recess.

56. The method of claim 53, wherein forming the electronic substrate comprises forming at least one dielectric layer, forming at least one bond pad, and forming at least one opening extending through the at least one dielectric layer, wherein the at least one resilient connector extends through the opening to contact the at least one bond pad.

57. The method of claim 53, wherein the electromagnetic interference structure substantially surrounding the at least one integrated circuit device.

58. The method of claim 53, further comprising attaching a backing plate on a side of the electronic substrate opposite the electromagnetic interference structure and wherein forming at least one resilient connector comprises forming at least one resilient connector extending between and electrically attaching the backing plate and the at least one integrated circuit device.
